(19) United States
(12) Patent Application Publication
(10) Pub. No.: US 2015/0114467 A1
(43) Pub. Date: Apr. 30, 2015

(54) DONOR-ACCEPTOR ALTERNATING CONJUGATED POLYMER AND SOLAR CELL DEVICE MANUFACTURED BY USING THE SAME

(71) Applicant: National Taiwan University, Taipei City (TW)

(72) Inventors: Wei-Fang SU, Taipei City (TW); Chien-An CHEN, Taipei City (TW); Chun-Yu CHANG, Taipei City (TW); Chun-Chih HO, Taipei City (TW)

(21) Appl. No.: 14/314,588

(22) Filed: Jun. 25, 2014

(30) Foreign Application Priority Data
Oct. 30, 2013 (TW) 102139316

(51) Int. Cl. H01L 51/00; H01L 51/42

(52) U.S. Cl. CPC H01L 51/0072; H01L 51/42
USPC 136/263; 528/9

(57) ABSTRACT

The present invention provides a donor-acceptor alternating conjugated polymer represented by the following chemical formula (1):

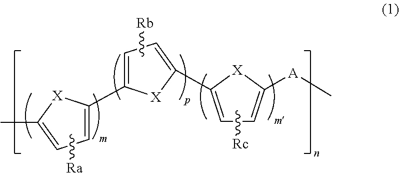

wherein, X, A, Ra, Rb, Rc, m, p, m′, and n are the same as those defined in the present specification; and a solar cell device manufactured by using the same.

### CROSS REFERENCE TO RELATED APPLICATION

This application claims the benefits of the Taiwan Patent Application Serial Number 102139316, filed on Oct. 30, 2013, the subject matter of which is incorporated herein by reference.

### BACKGROUND OF THE INVENTION

1. Field of the Invention

The present invention relates to a donor-acceptor alternating conjugated polymer and, more particularly to a conjugated polymer which is suitable for manufacturing a polymer solar cell device, and a field emitting transistor (FET).

2. Description of Related Art

International oil crisis, nuclear crisis, and global warming are getting severe recently, and many scientists focus on developing renewable energy. The known renewable energy comprise hydropower, wind energy, geothermal energy, sun energy and so on. Among all the renewable energy, most of the scientists focus on the sun energy since it is abundant and inexhaustible. Nowadays, many kinds of solar cell devices have been developed, and can be classified into three generations. The first generation of the solar cell device is silicon solar cell devices, the second generation thereof is thin film solar cell devices such as amorphous solar cell devices and CdTe solar cell devices; and the third generation thereof is developing device such as dye-sensitized solar cell devices, polymer solar cell devices, and other novel solar cell devices. The light absorption material used in recent solar cell device is mainly semiconductor material, wherein p-type and n-type semiconductor materials are used together, the p-type or n-type semiconductor material can absorb light to generate excitons, and the excitons diffuse to the p-n junction to form electron-hole pairs. The electrons of the electron-hole pairs are attracted to the negative electrode of the solar cell device and pass through the n-type semiconductor material, and the holes thereof are attracted to the positive electrode and pass through the p-type semiconductor material. Among the three generations of the solar cell devices, the first generation devices using silicon as the main material are well developed. The first generation devices can exhibit high power conversion efficiency (PCE) about 20% and long life span and become the main stream of the commercialized solar cell; but the first generation devices still have limitation of expensive production cost. The second generation devices such as the thin film solar cell devices can be manufactured by different manners and in low production cost and exhibit PCE about 10-20%. Hence, the second generation devices have been widely applied to consumer electronic products such as watches and calculators. However, the vacuum process for manufacturing the same still cause the production cost thereof increased. On the contrary, although the third generation solar cell devices are still developed, these devices have the advantages of low production cost and can be manufactured in large area.

The firstly developed polymer solar cell device has a bilayer heterojunction configuration, i.e. positive electrode/p-type semiconductor thin film/n-type semiconductor thin film/negative electrode. In the path of photoelectron conversion, the diffusion of the excitons is one important factor relating to the device efficiency. Some studies indicate that the diffusion distance of excitons is about 5-14 nm, so the thickness of the bilayer has to be controlled in a range of 5-14 nm to ensure the excitons can effectively diffuse to the p-n junction. However, the thin film having 5-14 nm thickness is hard to be manufactured, and can only absorb few amount of solar energy. In addition, the procedure for manufacturing this structure still has its limitation. For example, the solvent for dissolving the n-type semiconductor material has to be not capable of dissolving the p-type semiconductor material, so that the solvent used in the n-type semiconductor material does not damage the formed p-type semiconductor thin film. Based on the aforementioned limitation, only few kinds of material can be used therein. In recent years, the polymer solar cell devices having bulk heterojunction configuration are developed to solve the aforementioned problems.

The structure of the polymer solar cell devices having bulk heterojunction configuration is positive electrode/p-type semiconductor and n-type semiconductor hybrid thin film/negative electrode. The hybrid thin film is configured with p-type semiconductor domain and n-type semiconductor domain. The domain size is decided by the phase separation between the p-type and the n-type semiconductor. Preferably, the domain size is controlled in 5-14 nm to ensure the excitons effectively diffusing to the p-n junction. Since the semiconductor domain randomly distributed in the hybrid thin film, more p-n junctions can be generated. In addition, whether the excitons can successfully diffuse to the p-n junctions or not is decided by the domain size, not by the thickness of the thin film. Therefore, the thickness of the hybrid thin film can be enhanced to more than 100 nm to increase the absorption of the solar energy, so the disadvantages of the early solar cell devices can be improved.

Some studies further indicate that a polymer having a donor-acceptor pair can achieve the purpose of obtaining ideal energy gap, wherein the design of the donor-acceptor pair is based on Molecular Orbital Theory. When atoms or molecules having different energy levels are conjugated together to form a new molecule, a new energy level is generated, and the energy gap in the new molecule is smaller than that in the original atoms and molecules.

In addition, the crystallization of the semiconductor material is positively related to the charge mobility and short circuit current (Jsc). Some studies even indicate that the structure symmetry of the donor group is related to the hole mobility. In the donor having centrosymmetric structure, the structure thereof is close to a linear structure, so the crystallization thereof is good, resulting in high hole mobility. However, in the donor having axisymmetric structure, the structure thereof is a curve structure, so the crystallization thereof is relative poor, resulting in low hole mobility.

However, in the bulk heterojunction configuration, solubility of the semiconductor material is one important issue. In order to make the excitons effectively diffuse to the p-n junctions, the domain size has to be controlled in 5-14 nm. Hence, a micro phase separation has to be generated between the donor-acceptor conductive polymer with low energy gap and the nano carbon cluster. In addition, the donor having a centrosymmetric structure has better molecular arrangement and therefore low solubility. On the other hand, the donor having axisymmetric structure has relatively good solubility. Hence, both the crystallization and the solubility of the donor-acceptor conductive polymer with low energy gap have to be considered at the same time to effectively improve the short circuit current (Jsc) of the device.

In conclusion, it is desirable to provide a donor-acceptor alternating conjugated polymer having proper structure symmetry and suitable conjugated length in the donor group, which is suitable for manufacturing a polymer solar cell device, and a field emitting transistor (FET).

### SUMMARY OF THE INVENTION

An objective of the present invention is to provide a donor-acceptor alternating conjugated polymer, which is suitable for manufacturing a polymer solar cell device, and a field emitting transistor (FET).

The donor-acceptor alternating conjugated polymer of the present invention can be represented by the following formula (a):

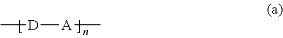

wherein D is a donor, which is plural conjugated aromatic groups unsubstituted or substituted with a substitution; and A is an acceptor conjugated with D, in which the energy gap between the LUMO of A and the HOMO of D is less than 2 eV.

In the present invention, the formula (a) can be the following formula (1):

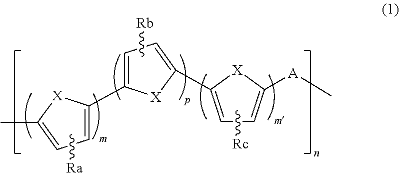

wherein,

### X may be O, N, S, Se, Te or Po;

each A may be independently a substituted or unsubstituted functional group containing at least one aryl or heteroaryl;
each Ra, Rb and Rc may be independently selected from the group consisting of: H, C₁₋₃₀ alkyl, C₃₋₃₀ cycloalkyl, C₃₋₃₀ heterocycloalkyl, C₆₋₃₀ aryl, C₅₋₃₀ heteroaryl, —R₁COOR₁′, —R₂COR₂′, and —R₃—O—R₃′; in which each R₁, R₂ and R₃ is independently a bond or C₁₋₃₀ alkyl, and each R₁′, R₂′ and R₃′ is independently H or C₁₋₃₀ alkyl. In addition, in the space formed by the heteroaryl groups substituted with Ra, Rb and Rc, the functional groups Ra and Rc can be centrosymmetric or axisymmetric to each other.

In the aforementioned formula (1), preferably, each Ra and Rc is independently C₃₋₁₆ alkyl, and Rb is H.

In the aforementioned formula (1), m, m′ and p is independently an integer, wherein m+m′+p=4˜10 and m=m′; and n is an integer ranging from 10 to 150. In one preferred embodiment, each m and m′ is independently 1˜2, and p is 1˜2. In addition, in a further preferred embodiment, both m and m′ are 2, and p is 2.

In the aforementioned formula (1), the energy gap between the lowest unoccupied molecular orbital (LUMO) of A and the highest occupied molecular orbital (HOMO) of D is less than 2 eV, and preferably less than 1.6 eV. The group A is not particularly limited, as long as the energy level thereof satisfies the aforementioned criteria, and it has excellent light absorption property, good crystallization, and fine charge carrier mobility. For example, each A is independently selected from the group consisting of:

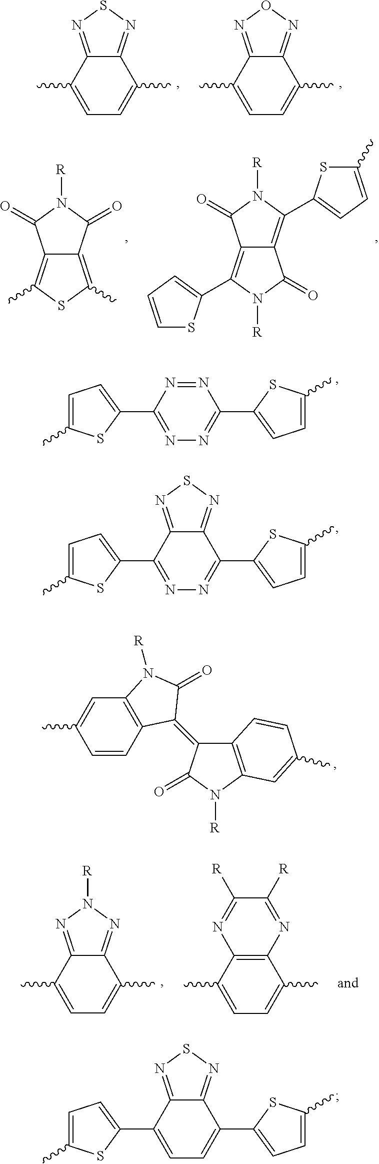

wherein, each R may be independently selected from the group consisting of: H, C₁₋₃₀ alkyl, C₃₋₃₀ cycloalkyl, C₃₋₃₀ heterocycloalkyl, C₆₋₃₀ aryl, C₅₋₃₀ heteroaryl, —R₁COOR₁′, —R₂COR₂′, and —R₃—O—R₃′; in which each R₁, R₂ and R₃ is independently a bond or C₁₋₃₀ alkyl, and each R₁′, R₂′ and R₃′ is independently H or C₁₋₃₀ alkyl. In one preferred embodiment of the present invention, R is linear or branch C₃₋₁₆ alkyl.

In addition, in one preferred embodiment of the present invention, A is isoindigo.

In one preferred embodiment of the present invention, both m and m′ are 1, and p is 2. In this case, the polymer represented by the aforementioned formula (1) is the following formula (2):

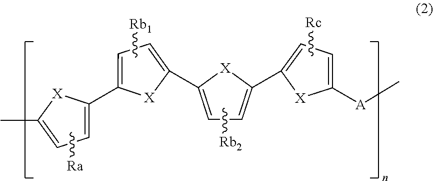

wherein both Rb₁ and Rb₂ are H, and Ra is identical to Rc. For example, both Ra and Rc are C₁₋₃₀ alkyl, wherein the space formed by Ra (including the aromatic ring bonded thereto) and Rc (including the aromatic ring bonded thereto) is centrosymmetric to each other.

Herein, A in the aforementioned formula (2) preferably is isoindigo. In addition, both Ra and Rc may be C₁₋₃₀ alkyl, and preferably is C₃₋₁₆ alkyl.

In another preferred embodiment of the present invention, both m and m′ are 2, and p is 1. In this case, the polymer represented by the aforementioned formula (1) is the following formula (3):

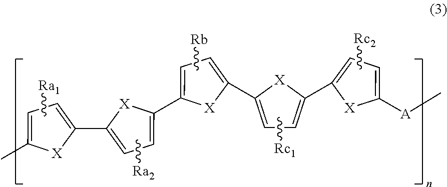

wherein Rb is H, and all Ra₁, Ra₂, Rc₁ and Rc₂ are identical. In this case, Ra₁ and Ra₂ (including the aromatic rings bonded thereto) and Rc₁ and Rc₂ (including the aromatic rings bonded thereto) is axisymmetric to each other.

Herein, A in the aforementioned formula (3) preferably is isoindigo. In addition, all Ra₁, Ra₂, Rc₁ and Rc₂ may be C₁₋₃₀ alkyl, and preferably is C₃₋₁₆ alkyl.

In further another preferred embodiment of the present invention, both m and m′ are 2, and p is 2. In this case, the polymer represented by the aforementioned formula (1) is the following formula (4):

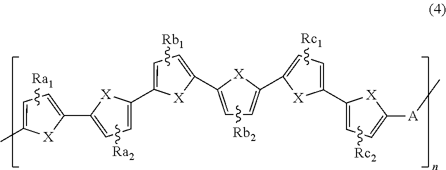

wherein both Rb₁ and Rb₂ are H, and all Ra₁, Ra₂, Rc₁ and Rc₂ are identical. In this case, Ra₁ and Ra₂ (including the aromatic rings bonded thereto) and Rc₁ and Rc₂ (including the aromatic rings bonded thereto) is centrosymmetric to each other.

Herein, A in the aforementioned formula (4) preferably is isoindigo. In addition, all Ra₁, Ra₂, Rc₁ and Rc₂ may be C₁₋₃₀ alkyl, and preferably is C₃₋₁₆ alkyl.

In the present invention, the term “centrosymmetric” means that two functional groups are mirror symmetric to each other with a point as a symmetric center in a space. For example, in the aforementioned formulas (2) and (4), the point as the symmetric center is located on the bond between two aromatic groups substituted with Rb₁ and Rb₂. The term “axisymmetric” means two functional groups are mirror symmetric to each other with a line as a symmetric axis in a space. For example, in the aforementioned formula (3), the symmetric axis is the line passing through the X of the aromatic group and parallel to the paper plane, so that the Ra₁ is symmetric to Rc₂ as well as Ra₂ is symmetric to Rc₁.

In the present invention, without particularly limitation, the term “alkyl” refers to the liner or branch hydrocarbon group with a single valence; the term “cycloalkyl” refers to the non-aromatic 5-8 membered monocyclic ring system, 8-12 membered bicyclic ring system, or 11-14 membered tricyclic ring system; the term “heterocyloalkyl” refers to the non-aromatic 5-8 membered monocyclic, 8-12 membered bicyclic, or 11-14 membered tricyclic ring system having at least one hetero atom selected from the group consisting of N, O, S, Se, P and B; the term “aryl” refers to the C₆ monocyclic, C₁₀ bicyclic or C₁₄ tricyclic aromatic ring system, which comprises but is not limited to: phenyl, naphthyl and anthryl; the term “heteroaryl” refers to aromatic 5-8 membered monocyclic, 8-12 membered bicyclic, or 11-14 membered tricyclic ring system having at least one hetero atom selected from the group consisting of N, O, S, Se, P, Si, Ge and B.

Another objective of the present invention is to provide a polymer solar cell device, comprising: a first electrode; an active layer deposited on the first electrode, wherein a material thereof comprises: an n-type semiconductor material; and a p-type semiconductor material made of the polymer represented by the aforementioned formulas (1)˜(4); and second electrode deposited on the active layer.

In the polymer solar cell device of the present invention, the n-type semiconductor material has to have high electron mobility and LUMO with a relative low energy level, so that the electron in the LUMO of the p-type semiconductor material can be excited to the n-type semiconductor material. The n-type semiconductor material may comprise at least one selected from the group consisting of: a nano carbon cluster such as PC₆₁BM and PC₇₁BM, an n-type semiconductor polymer, and n-type semiconductor nanoparticles. Preferably, the nano carbon cluster is used as the n-type semiconductor material in the polymer solar cell device of the present invention. It is because that an ideal micro-phase separation can be obtained in the mixture of the nano carbon cluster and the polymer when the nano carbon cluster is used as the n-type semiconductor material. For example, when a carbon cluster having 5-14 nm is used in the present invention, excitons can effectively diffuse to the p-n junction.

In one embodiment of the present invention, the material of the active layer may further comprise an additive. The material of the additive is not particularly limited, as long as it can facilitate the charge transportation to improve the device efficiency. For example, the additive can comprise at least one of 1,8-diiodooctane (DIO) and 1-chloronaphthalene (CN).

In addition, in one embodiment of the present invention, the first electrode may be a transparent electrode, such as an ITO electrode.

Furthermore, in one embodiment of the present invention, the second electrode may be made of at least one selected from the group consisting of Al, Ca, Ag and Au.

In one embodiment of the present invention, the polymer solar cell device may further comprise: a hole transporting layer deposited between the first electrode and the active layer, and the material thereof can be PEDOT:PSS.

In conclusion, the present invention can provide a polymer with a donor group having good symmetry and ideal conjugated length. In addition, the polymer provided in the present invention has wide light adsorption range, and good crystallization and solubility, and therefore the solar cell device manufactured with the same can exhibit improved short circuit current (Jsc) and photoelectrical conversion efficiency.

Other objectives, advantages, and novel features of the invention will become more apparent from the following detailed description when taken in conjunction with the accompanying drawings.

### BRIEF DESCRIPTION OF THE DRAWINGS

FIG. 1 is a perspective view of a solar cell device of the present invention; and

FIG. 2 is a voltage-circuit curve of a solar cell device of the present invention.

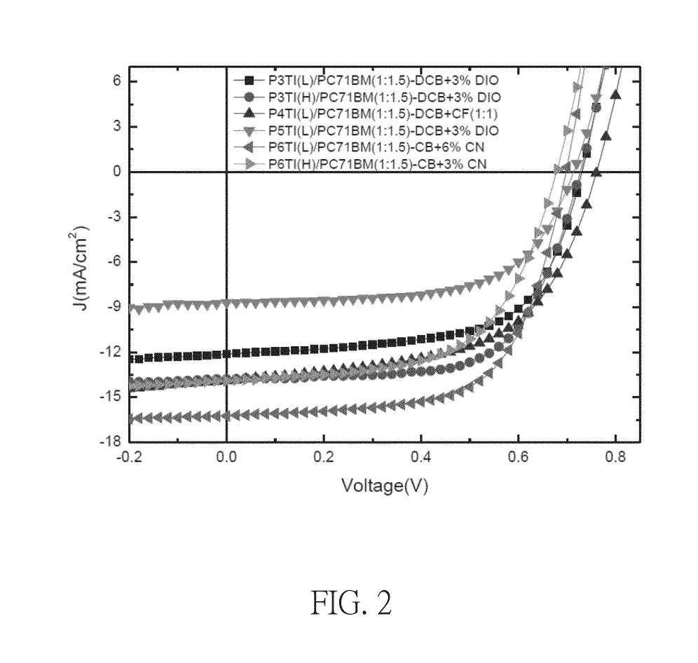

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

### EMBODIMENT

### Preparation Example 1

### Synthesis of 3-Octylthiophene (Compound 1)

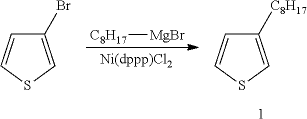

1-bromooctane (53.30 g, 0.276 mole) was slowly added into a flask containing Mg (8.95 g, 0.368 mole) and 300 ml anhydrous ether at 0° C., followed by reacting the obtained mixture at room temperature for 1 hr. Next, the solution was introduced into a flask containing 3-bromothiophen) (30.00 g, 0.184 mole), Ni(dppp)Cl₂ (200 mg, 0.368 mmole) and 300 ml anhydrous ether with a double end pin, followed by reacting the mixture for 10 hr. After the reaction was completed, 1 M HCl (200 ml) was added therein to stop the reaction. The mixture was extracted with ether, and then anhydrous MgSO₄ was added into the organic layer. Then, the solvent contained therein was removed with a centrifuge; and the product was distillated under a reduced pressure to obtain a colorless transparent liquid (compound 1) (28.54 g, 79%), wherein the boiling point of the desired compound 1 is 106° C. under 3 torr.

¹H NMR (400 MHz, CDCl3, δ): 7.24 (dd, J=4.9 Hz, J=3.0 Hz, 1H), 6.98-6.89 (m, 2H), 2.63 (t, J=7.6 Hz, 2H), 1.63 (qui, J=6.8 Hz, 2H), 1.45-1.17 (m, 10H), 0.89 (t, J=6.8 Hz, 3H)

### Preparation Example 2

### Synthesis of Trimethyl(4-octylthiophen-2-yl)stannane (Compound 2)

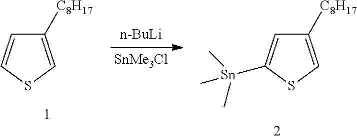

At −78° C., 40 ml anhydrous hexane (0.1 mole) solution containing 2.5 M n-BuLi was added into a flask containing the compound 1 (19.64 g, 0.1 mole) and 100 ml anhydrous tetrahydrofuran (THF). The mixture was reacted at −78° C. for 1 hr, followed by reacting at room temperature for another 1 hr. Then, at −78° C., 100 ml anhydrous THF (0.1 mole) solution containing 1 M trimethyltin chloride was added therein, followed by reacting the obtained mixture at room temperature for 10 hr. The resultant was extracted with hexane, and then anhydrous MgSO₄ was added into the organic layer. After the solvent contained therein was removed with a centrifuge, the resultant was purified with a celite gel by using hexane as an eluent to obtain light yellow liquid (29.45 g, 82%).

¹H NMR (400 MHz, CDCl3, δ): 7.20 (s, 1H), 7.01 (s, 1H), 2.65 (t, J=7.6 Hz, 2H), 1.64 (qui, J=7.6 Hz, 2H), 1.45-1.17 (m, 10H), 0.89 (t, J=6.7 Hz, 3H), 0.36 (s, 9H)

### Preparation Example 3

### Synthesis of 7-(Bromomethyl)pentadecane) (Compound 3)

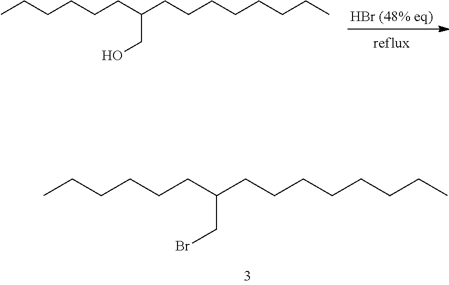

2-hexyl-1-decanol (40.00 g, 0.165 mole) was mixed with 40 wt % hydrogen bromide aqueous solution (100.00 g, 0.494 mole), followed by heating and refluxing the obtained mixture for 10 hr. After the reaction was completed, the resultant was extracted with toluene, and then anhydrous MgSO₄ was added into the organic layer. After the solvent contained therein was removed with a centrifuge, the resultant was purified with a silica gel by using toluene as an eluent to obtain colorless transparent liquid (47.86 g, 95%).

¹H NMR (400 MHz, CDCl3, δ): 3.45 (d, J=4.8 Hz, 2H), 1.63-1.55 (m, 1H), 1.45-1.17 (m, 24H), 0.93-0.81 (m, 6H)

### Preparation Example 4

### Synthesis of (E)-6,6′-Dibromo-[3,3′-biindolinylidene]-2,2′-dione (Compound 4)

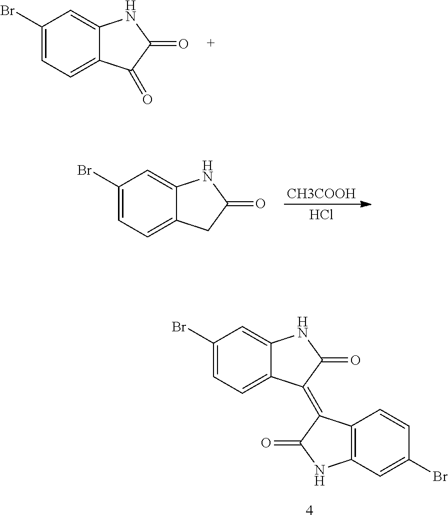

6-bromooxindole (23.45 g, 0.110 mole), 6-bromoisatin (25.00 g, 0.110 mole), acetic acid (750 ml) and HCl (5 ml) was mixed, followed by heating and refluxing the obtained mixture for 24 hr. After the reaction was completed and cooled, the resultant was filtrated, followed by eluting the resultant repeatedly until natural deep brown solid was obtained (45.53 g, 98%).

¹H NMR (400 MHz, D6-DMSO, δ): 11.11 (s, 2H), 9.03 (d, J=8.6 Hz, 2H), 7.22 (d, J=8.7 Hz, 2H), 7.03 (s, 2H)

### Preparation Example 5

### Synthesis of (E)-6,6′-Dibromo-1,1′-bis(2-hexyldecyl)-[3,3′-biindolinylidene]-2,2′-dione (Compound 5)

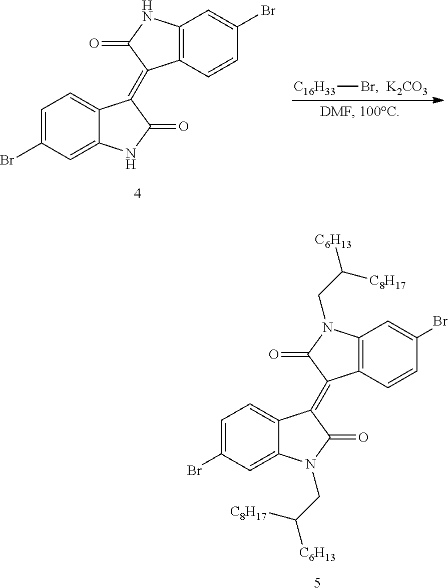

The obtained compound 4 (10.00 g, 23.81 mmole), K₂CO₃ (32.90 g, 238.06 mmole), the obtained compound 3 (14.54 g, 47.61 mmole) and 100 ml anhydrous dimethylformamide was mixed, followed by heating the mixture to 100° C. and reacting for 24 hr. After the reaction was completed, the resultant was extracted with ether, and then anhydrous MgSO₄ was added into the organic layer. After the solvent contained therein was removed with a centrifuge, the resultant was purified with a silica gel by using hexane/dichloromethane (1:1) as an eluent to obtain red solid (20.68 g, 95%).

¹H NMR (400 MHz, CDCl3, δ): 9.07 (d, J=8.6 Hz, 2H), 7.16 (d, J=8.6 Hz, J=1.8 Hz, 2H), 6.89 (d, J=1.8 Hz, 2H), 3.62 (d, J=7.5 Hz, 4H), 2.00-1.80 (m, 2H), 1.45-1.17 (m, 48H), 0.93-0.81 (m, 12H)

### Preparation Example 6

### Synthesis of (E)-1,1′-Bis(2-hexyldecyl)-6,6′-bis(4-octylthiophen-2-yl)-[3,3′-biindolinylidene]-2,2′-dione (Compound 6)

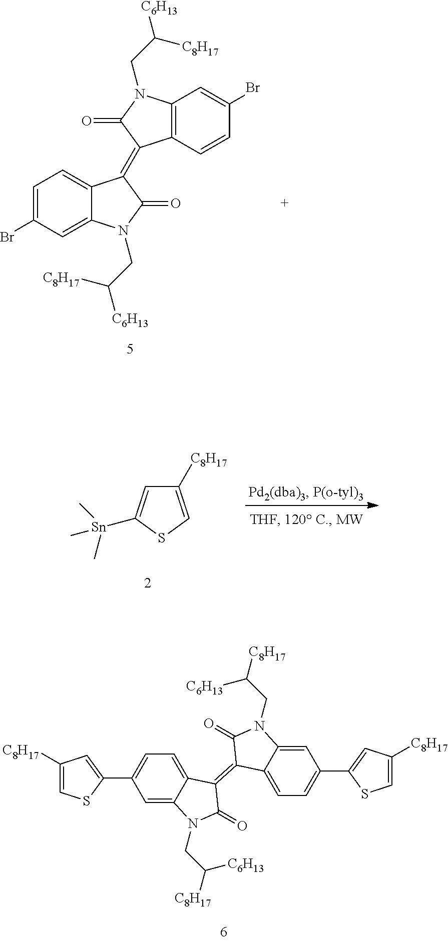

The obtained compound 2 (10.00 g, 27.84 mmole), the obtained compound 5 (10.00 g, 11.50 mmole), Pd₂(dba)₃ (30.00 mg, 0.032 mmole), P(o-tol)₃ (50.00 mg, 0.16 mmole) and 150 ml anhydrous THF was mixed, followed by heating and refluxing the mixture for 10 hr. After the reaction was completed, the solvent contained therein was removed with a centrifuge, and then the resultant was purified with a silica gel by using hexane/dichloromethane (2:1) as an eluent to obtain dark red solid (12.28 g, 97%).

¹H NMR (400 MHz, CDCl3, δ): 9.15 (d, J=8.4 Hz, 2H), 7.30-7.20 (m, 4H), 6.98-6.91 (m, 4H), 3.70 (d, J=7.5 Hz, 4H), 2.63 (t, J=7.6 Hz, 4H), 1.98-1.84 (m, 2H), 1.66 (qui, J=7.1 Hz, 4H), 1.45-1.17 (m, 68H), 0.93-0.81 (m, 18H)

### Preparation Example 7

### Synthesis of (E)-6,6′-Bis(5-bromo-4-octylthiophen-2-yl)-1,1′-bis(2-hexyldecyl)-[3,3′-biindolinylidene]-2,2′-dione (Compound 7)

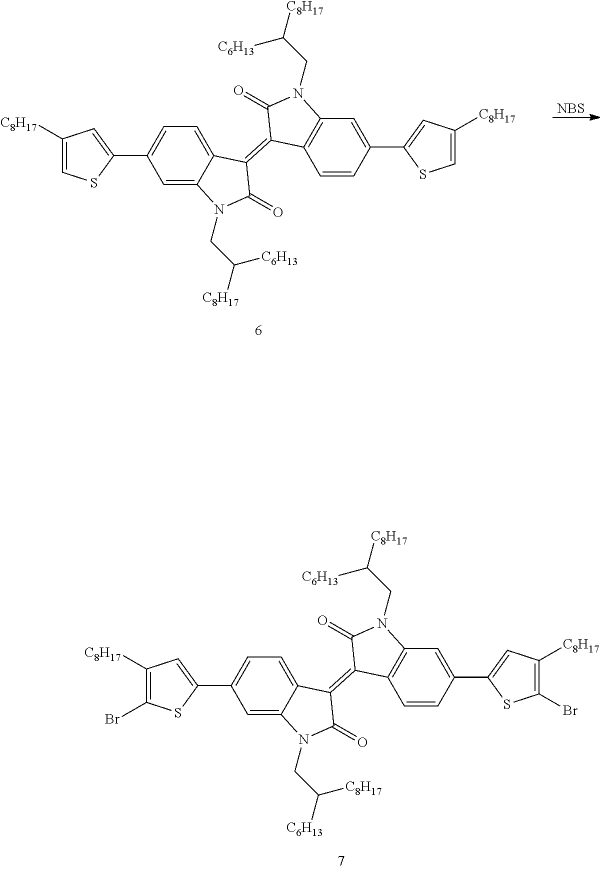

The obtained compound 6 (12.28 g, 11.16 mmole) was dissolved in 100 ml THF. After the compound 6 was dissolved completely, N-bromosuccinimide (3.98 g, 22.33 mmole) was added into the mixture in 8 batches, and every 15 min for 1 batch. After all N-bromosuccinimide was added therein, the mixture was reacted for 10 hr. Then, the solvent contained therein was removed with a centrifuge, and then the resultant was purified with a silica gel by using hexane/dichloromethane (2:1) as an eluent to obtain dark red solid (12.22 g, 87%).

¹H NMR (400 MHz, CDCl3, δ): 9.14 (d, J=8.4 Hz, 2H), 7.18 (dd, J=8.4 Hz, J=1.3 Hz, 2H), 7.08 (s, 2H), 6.84 (d, J=1.1 Hz, 2H), 3.67 (d, J=7.2 Hz, 4H), 2.61-2.56 (m, 4H), 1.94-1.84 (m, 2H), 1.66 (qui, J=7.5 Hz, 4H), 1.45-1.17 (m, 68H), 0.93-0.81 (m, 18H)

### Preparation Example 8

### Synthesis of (E)-6,6′-Bis(3,4′-dioctyl-[2,2′-bithiophen]-5-yl)-1,1′-bis(2-hexyldecyl)-[3,3′-biindolinylidene]-2,2′-di one (Compound 8)

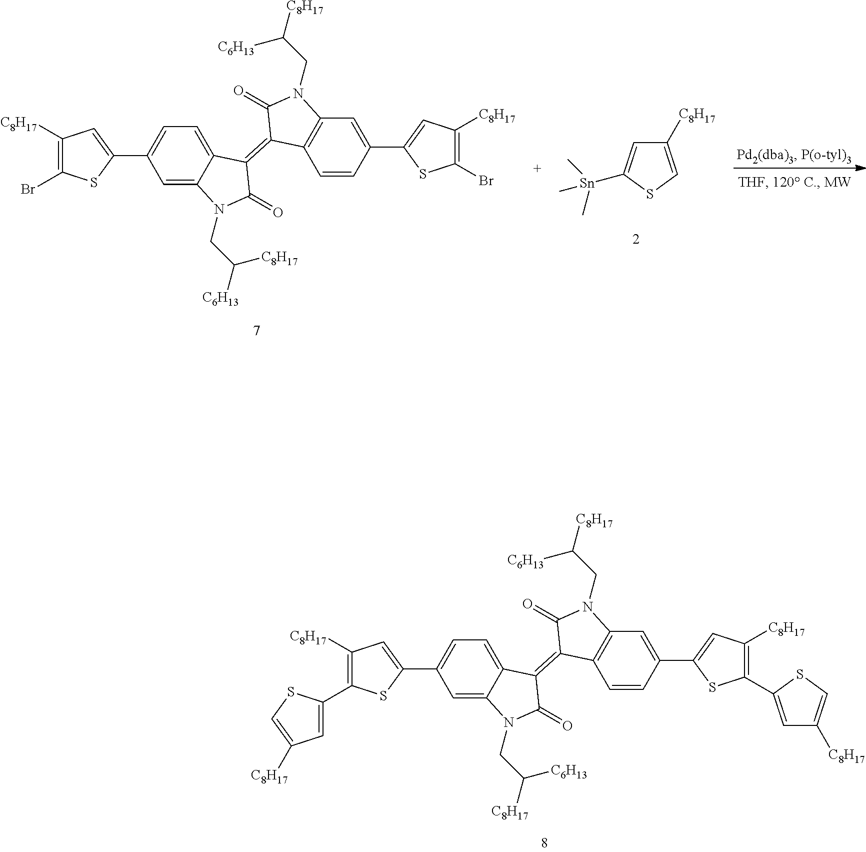

The obtained compound 2 (4.28 g, 11.92 mmole), the obtained compound 7 (6.00 g, 4.77 mmole), Pd₂(dba)₃ (10 mg, 0.01 mmole), P(o-tyl)₃ (17 mg, 0.05 mmole) and 50 ml anhydrous THF were mixed, followed by heating and refluxing the mixture for 10 hr. After the reaction was completed, the solvent contained therein was removed with a centrifuge, and then the resultant was purified with a silica gel by using hexane/dichloromethane (2:1) as an eluent to obtain dark purple solid (7.03 g, 99%).

¹H NMR (400 MHz, CDCl3, δ): 9.15 (d, J=8.4 Hz, 2H), 7.32-7.18 (m, 4H), 7.01 (s, 2H), 6.92 (s, 4H), 3.69 (d, J=6.9 Hz, 4H), 2.78 (t, J=7.7 Hz, 4H), 2.62 (t, J=7.7 Hz, 4H), 2.00-1.86 (m, 2H), 1.76-1.60 (m, 8H), 1.45-1.17 (m, 88H), 0.93-0.81 (m, 24H)

### Preparation Example 9

### Synthesis of (E)-6,6′-Bis(5′-bromo-3,4′-dioctyl-[2,2′-bithiophen]-5-yl)-1,1′-bis(2-hexyldecyl)-[3,3′-biindolinylide ne]-2,2′-dione (Compound 9)

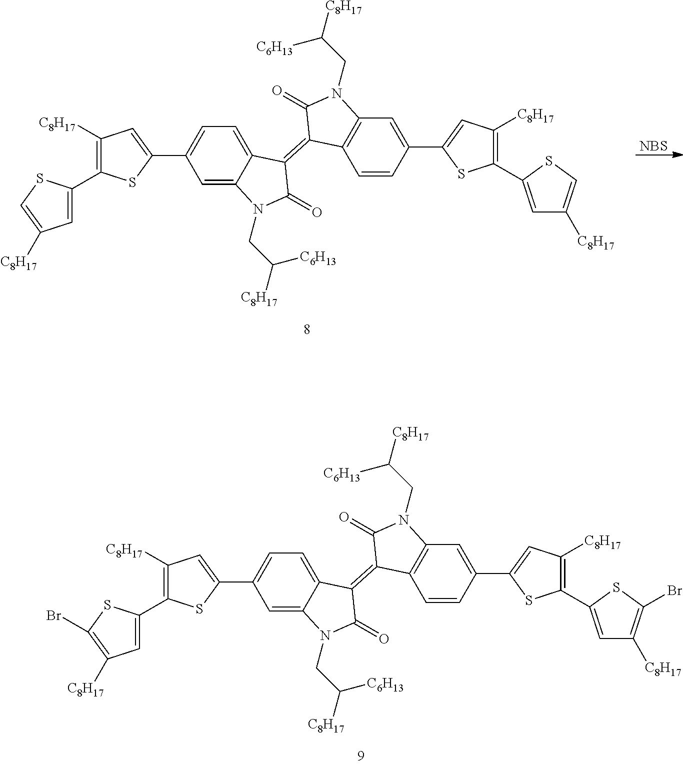

The obtained compound 8 (7.03 g, 4.72 mmole) was dissolved in 50 ml THF. After the compound 8 was dissolved completely, N-bromosuccinimide (1.68 g, 9.44 mmole) was added into the mixture in 8 batches, and every 15 min for 1 batch. After all N-bromosuccinimide was added therein, the mixture was reacted for 10 hr. Then, the solvent contained therein was removed with a centrifuge, and then the resultant was purified with a silica gel by using hexane/dichloromethane (3:1) as an eluent to obtain dark purple solid (6.92 g, 89%).

¹H NMR (400 MHz, CDCl3, δ): 9.15 (d, J=8.4 Hz, 2H), 7.35-7.12 (m, 4H), 6.91 (s, 2H), 6.86 (s, 2H), 3.69 (d, J=6.9 Hz, 4H), 2.73 (t, J=7.7 Hz, 4H), 2.57 (t, J=7.7 Hz, 4H), 1.98-1.84 (m, 2H), 1.72-1.60 (m, 8H), 1.45-1.17 (m, 88H), 0.93-0.81 (m, 24H)

### Preparation Example 10

### Synthesis of 2,5-Bis(trimethylstannyl)thiophene (Compound 10)

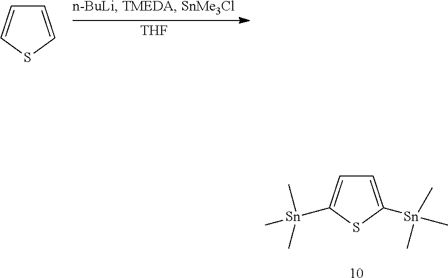

At 0° C., 40 ml anhydrous hexane (0.1 mole) solution containing 2.5 M n-BuLi was added into a flask containing thiophene (4.21 g, 0.05 mole), tetramethylethylenediamine (11.62 g, 0.1 mole) and 50 ml anhydrous THF, followed by reacting the mixture was reacted at 50° C. for 1 hr. Next, 100 ml anhydrous THF (0.1 mole) solution containing 1M trimethyltin chloride was added into the mixture at 0° C., followed by reacting the obtained mixture at room temperature for 10 hr. The resultant was extracted with hexane, and then anhydrous MgSO₄ was added into the organic layer. After the solvent contained therein was removed with a centrifuge, the resultant was purified and separated out with methanol to obtain white solid (19.05 g, 93%).

¹H NMR (400 MHz, CDCl3, δ): 7.38 (s, 2H), 0.37 (s, 18H)

### Preparation Example 11

### Synthesis of 5,5′-Bis(trimethylstannyl)-2,2′-bithiophene (Compound 11)

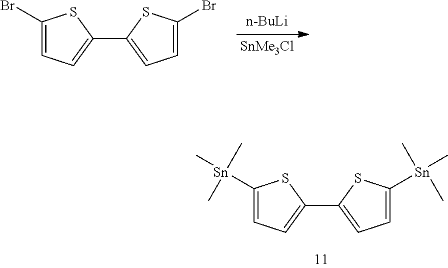

At −40° C., 20 ml anhydrous hexane (0.05 mole) solution containing 2.5 M n-BuLi was added into a flask containing 5,5′-dibromo-2,2′-bithiophene (8.10 g, 0.025 mole) and 100 ml anhydrous THF. The mixture was reacted at −40° C. for 1 hr, and then at room temperature for another 1 hr. Next, at −40° C., 50 ml anhydrous THF (0.05 mole) solution 1M trimethyltin chloride was added into the mixture, followed by reacting the obtained mixture at room temperature for 10 hr. After the reaction was completed, the resultant was extracted with hexane, and then anhydrous MgSO₄ was added into the organic layer. After the solvent contained therein was removed with a centrifuge, the resultant was purified separated out with methanol to obtain yellow solid (11.68 g, 95%).

¹H NMR (400 MHz, CDCl3, δ): 7.27 (d, J=3.2 Hz, 2H), 7.08 (d, J=3.3 Hz, 2H), 0.38 (s, 18H)

### Preparation Example 12

### Synthesis of P3TI (low molecular weight, Mn: 28 KDa, Mw: 60 KDa)

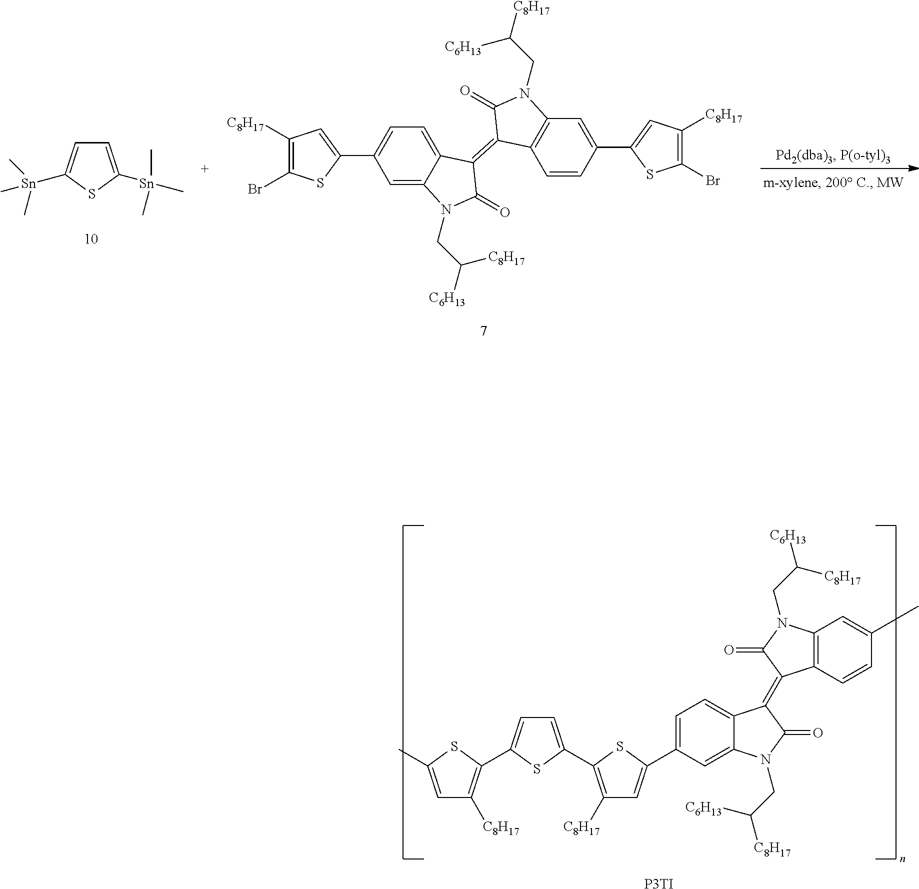

The obtained compound 10 (82 mg, 0.2 mmole), the obtained compound 7 (251 mg, 0.2 mmole), Pd₂(dba)₃ (6 mg, 0.007 mmole) and P(o-tyl)₃ (10 mg, 0.033 mmole) were added into a tube for a microwave reactor, and sealed. The air in the tube was removed with a vacuum system to 3×10⁻¹ torr, and then nitrogen was introduced therein. The aforementioned process was performed for three times. Next, m-xylene (4 ml) after degassing treatment was introduced into the sealed tube, and the sealed tube was placed into a microwave reactor to perform a microwave treatment. The condition for the reaction was as follows: 200° C., 300 W, 40 min for heat elevation, and 20 min retaining time at high temperature. After the reaction was completed, the mixture was added into methanol to separate out the polymer. Then, the obtained polymer was extracted with methanol and hexane through Soxhlet extraction process. After drying in a vacuum oven, a purplish red and metal glossy polymer was obtained (185 mg, 79%).

### Preparation Example 13

### Synthesis of P3TI (High Molecular Weight, Mn: 48 KDa, Mw: 117 KDa)

The obtained compound 10 (81.95 mg, 0.2 mmole), the obtained compound 7 (251.52 mg, 0.2 mmole), Pd₂(dba)₃ (6 mg, 0.007 mmole) and P(o-tyl)₃ (10 mg, 0.033 mmole) were added into a tube for a microwave reactor, and sealed. The air in the tube was removed with a vacuum system to 3×10⁻¹ torr, and then nitrogen was introduced therein. The aforementioned process was performed for three times. Next, m-xylene (4 ml) after degassing treatment was introduced into the sealed tube, and the sealed tube was placed into a microwave reactor to perform a microwave treatment. The condition for the reaction was as follows: 200° C., 300 W, 40 min for heat elevation, and 60 min retaining time at high temperature. After the reaction was completed, the mixture was added into methanol to separate out the polymer. Then, the obtained polymer was extracted with methanol and hexane through Soxhlet extraction process. After drying in a vacuum oven, a purplish red and metal glossy polymer was obtained (225 mg, 96%).

### Preparation Example 14

### Synthesis of P4TI (low molecular weight, Mn: 26 KDa, Mw: 55 KDa)

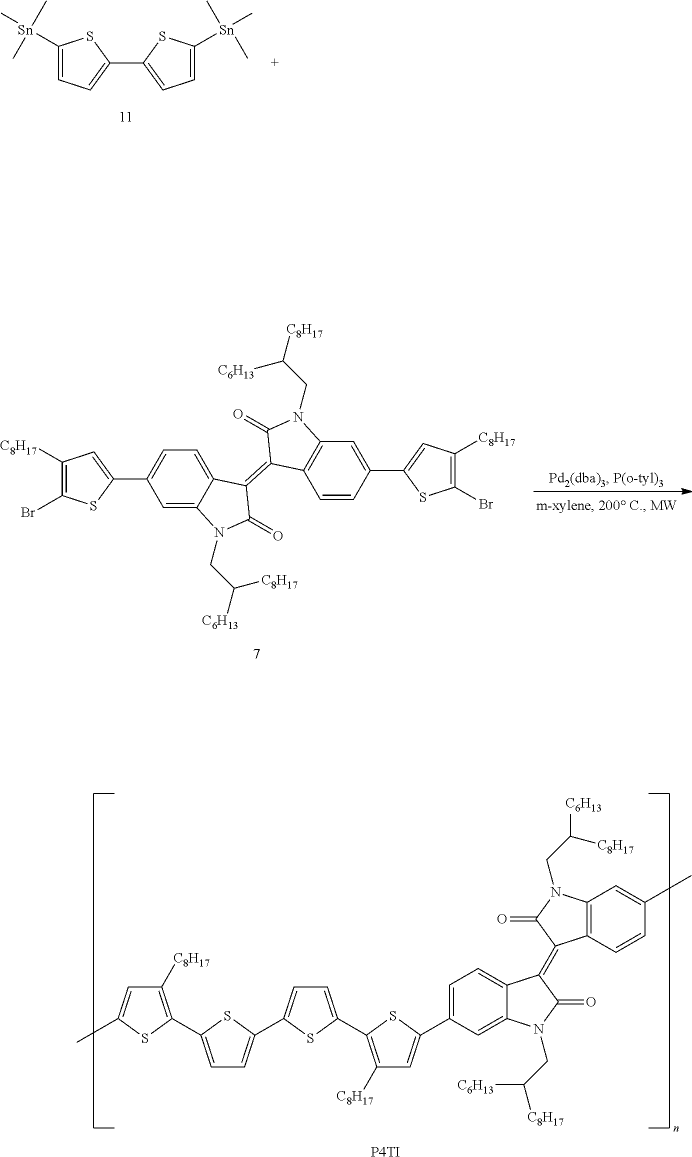

The obtained compound 11 (98.37 mg, 0.2 mmole), the obtained compound 7 (251.52 mg, 0.2 mmole), Pd₂(dba)₃ (6 mg, 0.007 mmole) and P(o-tyl)₃ (10 mg, 0.033 mmole) were added into a tube for a microwave reactor, and sealed. The tube was placed in a glove box (O₂<0.1 ppm) to remove oxygen contained therein. Next, m-xylene (4 ml) after degassing treatment was introduced into the sealed tube, and the sealed tube was placed into a microwave reactor to perform a microwave treatment. The condition for the reaction was as follows: 200° C., 300 W, 40 min for heat elevation, and 60 min retaining time at high temperature. After the reaction was completed, the mixture was added into methanol to separate out the polymer. Then, the obtained polymer was extracted with methanol, hexane and THF through Soxhlet extraction process. After drying in a vacuum oven, a purplish red and metal glossy polymer was obtained (200 mg, 81%).

### Preparation Example 15

### Synthesis of P5TI (low molecular weight, Mn: 28 KDa, Mw: 62 KDa)

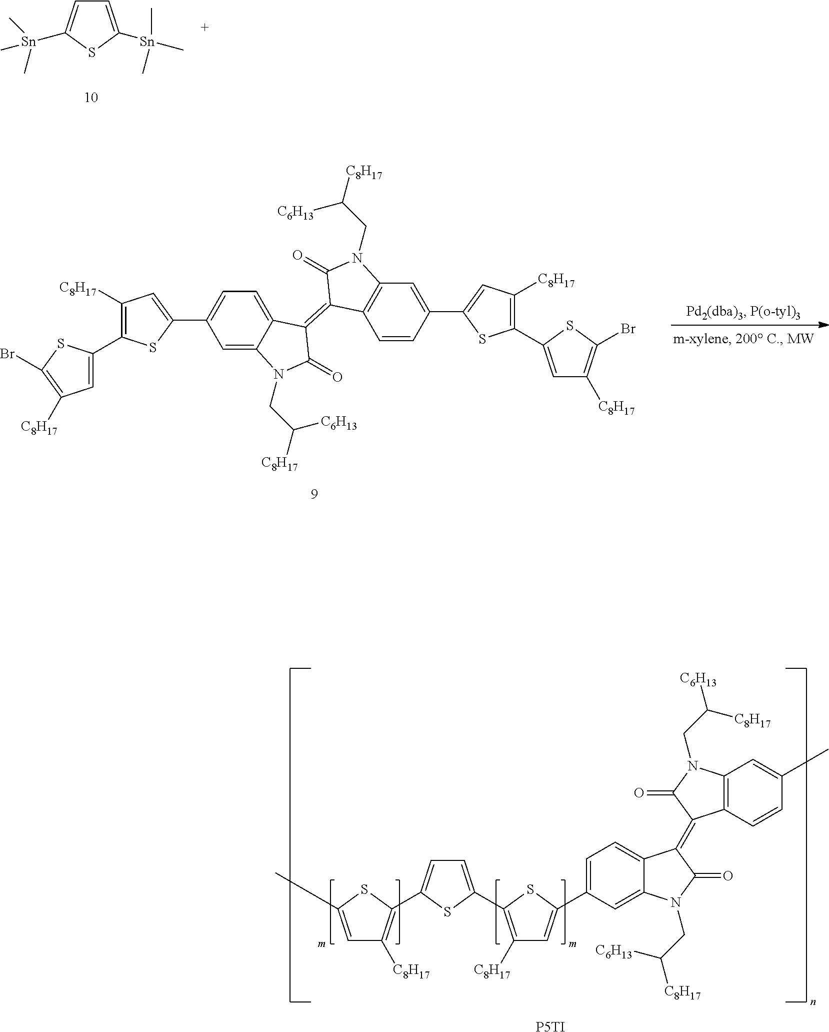

The obtained compound 10 (81.95 mg, 0.2 mmole), the obtained compound 9 (329.25 mg, 0.2 mmole), Pd₂(dba)₃ (6 mg, 0.007 mmole) and P(o-tyl)₃ (10 mg, 0.033 mmole) were added into a tube for a microwave reactor, and sealed. The air in the tube was removed with a vacuum system to 3×10⁻¹ torr, and then nitrogen was introduced therein. The aforementioned process was performed for three times. Next, m-xylene (4 ml) after degassing treatment was introduced into the sealed tube, and the sealed tube was placed into a microwave reactor to perform a microwave treatment. The condition for the reaction was as follows: 200° C., 300 W, 40 min for heat elevation, and 60 min retaining time at high temperature. After the reaction was completed, the mixture was added into methanol to separate out the polymer. Then, the obtained polymer was extracted with methanol and hexane through Soxhlet extraction process. After drying in a vacuum oven, a purplish red and metal glossy polymer was obtained (250 mg, 80%).

### Preparation Example 16

### Synthesis of P6TI (low molecular weight, Mn: 35 KDa, Mw: 63 KDa)

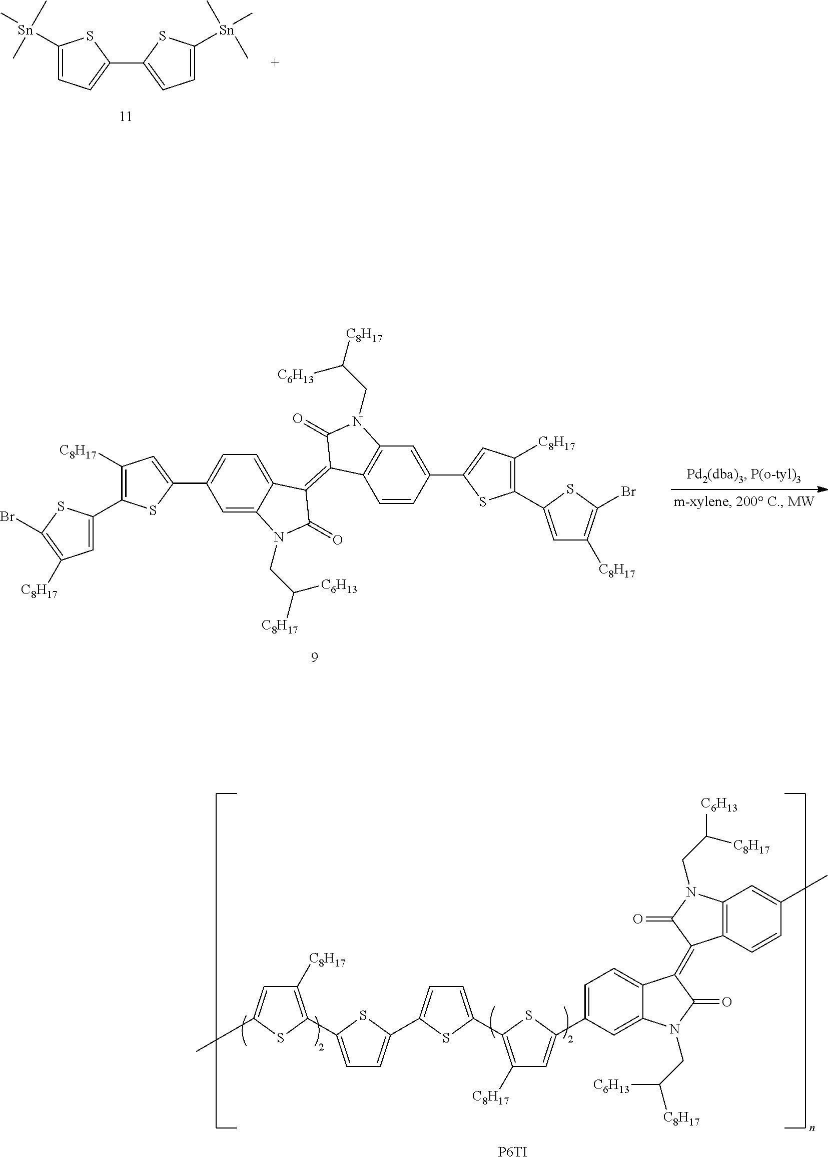

The obtained compound 11 (98.37 mg, 0.2 mmole), the obtained compound 9 (329.25 mg, 0.2 mmole), Pd₂(dba)₃ (6 mg, 0.007 mmole) and P(o-tyl)₃ (10 mg, 0.033 mmole) were added into a tube for a microwave reactor, and sealed. The tube was placed in a glove box (O₂<0.1 ppm) to remove oxygen contained therein. Next, m-xylene (4 ml) after degassing treatment was introduced into the sealed tube, and the sealed tube was placed into a microwave reactor to perform a microwave treatment. The condition for the reaction was as follows: 200° C., 300 W, 40 min for heat elevation, and 60 min retaining time at high temperature. After the reaction was completed, the mixture was added into methanol to separate out the polymer. Then, the obtained polymer was extracted with methanol, hexane and THF through Soxhlet extraction process. After drying in a vacuum oven, a purplish red and metal glossy polymer was obtained (210 mg, 66%).

### Preparation Example 17

### Synthesis of P6TI (High Molecular Weight, Mn: 45 KDa, Mw: 81 KDa)

The obtained compound 11 (98.37 mg, 0.2 mmole), the obtained compound 9 (329.25 mg, 0.2 mmole), Pd₂(dba)₃ (6 mg, 0.007 mmole) and P(o-tyl)₃ (10 mg, 0.033 mmole) were added into a tube for a microwave reactor, and sealed. The air in the tube was removed with a vacuum system to 3×10⁻¹ torr, and then nitrogen was introduced therein. The aforementioned process was performed for three times. Next, m-xylene (4 ml) after degassing treatment was introduced into the sealed tube, and the sealed tube was placed into a microwave reactor to perform a microwave treatment. The condition for the reaction was as follows: 200° C., 300 W, 40 min for heat elevation, and 60 min retaining time at high temperature. After the reaction was completed, the mixture was added into methanol to separate out the polymer. Then, the obtained polymer was extracted with methanol, hexane and THF through Soxhlet extraction process. After drying in a vacuum oven, a purplish red and metal glossy polymer was obtained (260 mg, 78%).

### Analytic Example 1

### Examination of the UV-Vis Absorption Spectra of PnTI Solution

10 mg of the obtained PnTI polymer (in which n is an integer of 3˜6) was added into 30 ml chloroform to obtain 0.33 mg/ml polymer solution. Next, the polymer solution was placed on a hot plate (50° C.) and stirred for 48 hr. When there was no precipitation observed and the solution was cooled, 3 ml of this solution was diluted with 17 ml of solvent, and the final concentration of the dilution was 0.05 mg/ml. The UV-Vis absorption spectrum of the final dilution with the concentration of 0.05 mg/ml was examined, and the results are shown in the following Table 1.

TABLE 1

| PnTI/ | λ1 | λ2 | λ3 | Λonset | Eg opt | λ1 red |
|---|---|---|---|---|---|---|
| Solvent | (nm) | (nm) | (nm) | (nm) | (eV) | shift (nm) |
| P3TI/CF* | 407 | 647 | — | 763 | 1.63 | 0 |
| P4TI/CF | 444 | 638 | 687 | 769 | 1.61 | 37 |
| P5TI/CF | 425 | 619 | — | 757 | 1.64 | 18 |
| P6TI/CF | 444 | 619 | — | 746 | 1.66 | 37 |

*CF: chloroform

### Analytic Example 2

### Examination of the UV-Vis Absorption Spectra of PnTI Thin Film

10 mg of the obtained PnTI polymer (in which n is an integer of 3˜6) was added into 1 ml chloroform to obtain 10 mg/ml polymer solution, except that the concentration of P4TI polymer solution is 5 mg/ml. Next, the polymer solution was placed on a hot plate (50° C.) and stirred for 48 hr. When there was no precipitation observed and the solution was cooled, 70 μl of the polymer solution was dropped onto 2 cm×2 cm quartz plate. A polymer thin film was formed through a spin coating machine (1000 rpm). Finally, the UV-Vis absorption spectrum of the obtained polymer thin film was examined, and the results are shown in the following Table 2.

TABLE 2

| PnTI/thin film | Λonset (nm) | Eg opt (eV) |
|---|---|---|
| P3TI | 782 | 1.59 |
| P4TI | 784 | 1.58 |
| P5TI | 785 | 1.58 |
| P6TI | 791 | 1.57 |

### Analytic Example 3

### Preparation of PnTI Sheet for CV Examination

10 mg of the obtained PnTI polymer (in which n is an integer of 3˜6) was added into 1 ml chloroform to obtain 10 mg/ml polymer solution, except that the concentration of P4TI polymer solution is 5 mg/ml. Next, the polymer solution was placed on a hot plate (50° C.) and stirred for 48 hr. When there was no precipitation observed and the solution was cooled, 50 μl of the polymer solution was dropped onto a 1 cm×2 cm conduction glass having ITO formed thereon (Luminescence Technology Corp., 10Ω). A polymer thin film was formed through a spin coating machine (1000 rpm), and sequentially examined with cyclic voltammetry (CV).

For CV, 0.1 M TBAP electrolyte solution (30 ml) was prepared with acetonitrile as a solvent. Then, 1 mg ferrocene was dissolved in 10 ml TBAP electrolyte solution and the resulting solution was placed into the measurement chamber for cyclic voltammetry. Herein, two Pt electrodes were used as a working electrode and a counter electrode respectively, and Ag/Ag+ electrode was used as a reference electrode. Before performing CV, nitrogen was introduced into the TBAP electrolyte solution to remove oxygen. After oxygen was removed completely, the CV examination was performed. The examination range of the oxidation potential of ferrocene was 0-0.8 V. After the oxidation potential of ferrocene was confirmed, the Pt working electrode was replaced with the aforementioned PnTI sheet, the electrolyte solution was TBAP electrolyte solution without ferrocene, and the counter electrode and the reference electrode were remained unchanged. During the CV examination, the examination range of the oxidation potential was defined as 0˜1.4 V, and that of the reduction potential was defined as 0˜−1.4 V. The results are shown in the following Table 3.

TABLE 3

| | Eox onset | HOMO | Ered onset | LUMO | Eg opt |
|---|---|---|---|---|---|
| PnTI | (V) | (eV) | (V) | (eV) | (eV) |
| P3TI | 1.02 | −5.49 | — | −3.90 | 1.59 |
| P4TI | 1.01 | −5.48 | — | −3.90 | 1.58 |
| P5TI | 0.97 | −5.44 | — | −3.86 | 1.58 |
| P6TI | 0.90 | −5.37 | — | −3.80 | 1.57 |

### Analytic Example 4

### Preparation of PnTI Sheet for Hole Mobility Examination

10 mg of the obtained PnTI polymer (in which n is an integer of 3˜6) was added into 1 ml o-dichlorobenzene to obtain 10 mg/ml polymer solution, except that the concentration of P4TI polymer solution is 5 mg/ml. Next, the polymer solution was placed on a hot plate (70° C.) and stirred for 48 hr. In order to obtain PnTI sheets having a structure of ITO/PnTI/Au, an ITO glass was cleaned sequentially with TL-1(NH₃:H₂O₂:H₂O=1:1:5), methanol and isopropanol cleaning solution, and ultra-sonicated for 15 min in each cleaning solution. Then, 70 μl of the polymer solution was dropped onto the 2 cm×2 cm ITO glass, and a polymer thin film was formed through a spin coating machine (1000 rpm). The semi-finished sheet was coated with 100 nm Au film through a thermal evaporation coater under 5×10⁻⁶ torr to obtain the PnTI sheet for hole mobility examination.

For hole mobility examination, the Au film and the ITO film as electrodes were electrically connected to outer circuit, and a voltage-circuit curve was recorded with an electric meter. The hole mobility of the PnTI sheet was calculated by the following equation:

$$J = \frac{9}{8} ɛμ \frac{{V}_{eff}^{2}}{{L}^{3}}$$

wherein J is current density; ∈=(relative dielectric constant of polymer)×(dielectric constant of vacuum), wherein relative dielectric constant of polymer is 3, and dielectric constant of vacuum is 8.85×10⁻¹² F/m; V_{eff} is effective potential; and L is a thickness of the polymer thin film. After calculation, the hole mobility μ of the polymer is shown in the following Table 4.

TABLE 4

| PnTI | Hole mobility (cm²/Vs) |
|---|---|
| P3TI | 3.64 × 10⁻⁴ |
| P4TI | 1.03 × 10⁻³ |
| P5TI | 1.20 × 10⁻⁴ |
| P6TI | 4.84 × 10⁻⁴ |

### Analytic Example 4

### Preparation of Polymer Solar Cell Device with PnTI

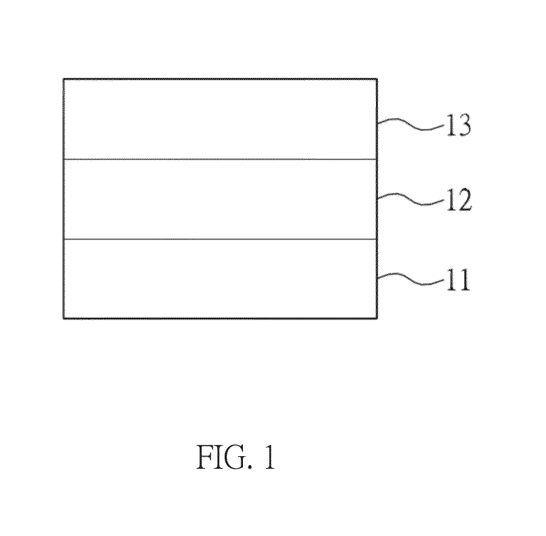

PnTI and PC₇₁BM were mixed in a weight ratio of 1:1.6, and a mixture solution for an active layer of the solar cell device was prepared with different solvent and additive (as shown in the following Table 5) according to the used PnTI. FIG. 1 is a perspective view of the polymer solar cell device of the present embodiment, wherein the material of the first electrode layer 11 is ITO, the material of the active layer 12 is PnTI:PC₇₁BM, and the material of the second electrode layer 13 is Ca and Al. in addition, a hole transporting layer is further deposited between the first electrode layer and the active layer. Herein, the PEDOT:PSS aqueous solution (Baytron P VP AI 4083) has to be filtrated with 0.20 μm PVDF filter.

First, an ITO glass was cleaned sequentially with TL-1(NH₃:H₂O₂:H₂O=1:1:5), methanol and isopropanol cleaning solution, and ultra-sonicated for 15 min in each cleaning solution. After the cleaning process, the ITO layer was treated with oxygen plasma for 15 min. Then, the filtrated PEDOT:PSS aqueous solution (100 μl) was dropped onto the 2 cm×2 cm ITO glass, and a PEDOT:PSS thin film was formed through a spin coating machine (5000 rpm). Next, the ITO/PEDOT:PSS substrate was placed on a hot plate (140° C.) for 20 min. Then, a PnTI:PC₇₁BM mixture (70 μl) was dropped onto the 2 cm×2 cm ITO/PEDOT:PSS substrate, and a PnTI:PC₇₁BM thin film was formed through a spin coating machine. The semi-finished sheet was coated with Ca and Al film through a thermal evaporation coater under 5×10⁻⁶ torr to obtain the polymer solar cell device of the present embodiment.

TABLE 5

| | | | Solvent:addictive | Stirring |
|---|---|---|---|---|
| PnTI | Solvent | Addictive | (volume ratio) | time (hr) |
| P3TI | o-dichlorobenzene | DIO | 97:3 | 48 |
| P4TI | Chloroform and | — | 100:0 | 48 |
| | o-dichlorobenzene | | | |
| | (1:1) | | | |
| P5TI | o-dichlorobenzene | DIO | 97:3 | 48 |
| P6TI | Chlorobenzene | CN | 94:6 | 48 |
| | | | (or 97:3) | |

In the aforementioned Table 5, DCB is an abbreviation of o-dichlorobenzene; CB is an abbreviation of chlorobenzene; CF is an abbreviation of chloroform; DIO is an abbreviation of 1,8-diiodooctane; and CN is an abbreviation of 1-chloronaphthalene.

Examination of Polymer Solar Cell Device with PnTI

The obtained polymer solar cell device was placed under an AM 1.5 G solar stimulator, 100 mW/cm² was provided onto the polymer solar cell device, and a voltage-circuit curve was recorded with an electric meter. The results are shown in the following Table 6 and Table 2.

TABLE 6

| PnTI | Jsc (mA/cm²) | Voc (Volts) | FF (%) | PCE (%) |
|---|---|---|---|---|
| Embodiment 12 | 12.14 | 0.73 | 62.83 | 5.57 |
| P3TI(L) | | | | |
| Embodiment 13 | 13.73 | 0.73 | 65.06 | 6.52 |
| P3TI(H) | | | | |
| Embodiment 14 | 13.91 | 0.76 | 57.15 | 6.04 |
| P4TI(L) | | | | |
| Embodiment 15 | 8.75 | 0.71 | 61.96 | 3.85 |
| P5TI(L) | | | | |
| Embodiment 16 | 16.34 | 0.70 | 63.82 | 7.24 |
| P6TI(L) | | | | |
| Embodiment 17 | 13.88 | 0.68 | 58.91 | 5.56 |
| P6TI(H) | | | | |

As shown in the aforementioned results, the present invention can provide a polymer with a donor group having good symmetry and ideal conjugated length. In addition, the polymer provided in the present invention has wide light adsorption range, and good crystallization and solubility, and therefore the solar cell device manufactured with the same can exhibit improved short circuit current (Jsc) and photoelectrical conversion efficiency.

Although the present invention has been explained in relation to its preferred embodiment, it is to be understood that many other possible modifications and variations can be made without departing from the spirit and scope of the invention as hereinafter claimed.

What is claimed is:

1. A polymer represented by the following formula (1): 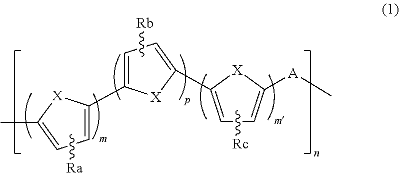
wherein,
X is O, N, S, Se, Te or Po;
each A is independently a substituted or unsubstituted functional group containing at least one aryl or heteroaryl;
each Ra, Rb and Rc is independently selected from the group consisting of: H, C₁₋₃₀ alkyl, C₃₋₃₀ cycloalkyl, C₃₋₃₀ heterocycloalkyl, C₆₋₃₀ aryl, C₅₋₃₀ heteroaryl, —R₁COOR₁′, —R₂COR₂′, and —R₃—O—R₃′; in which each R₁, R₂ and R₃ is independently a bond or C₁₋₃₀ alkyl, and each R₁′, R₂′ and R₃′ is independently H or C₁₋₃₀ alkyl;
m, m′ and p is independently an integer;
m+m′+p=4˜10;
m=m′; and
n is an integer ranging from 10 to 150.

2. The polymer as claimed in claim 1, wherein each A is independently selected from the group consisting of: 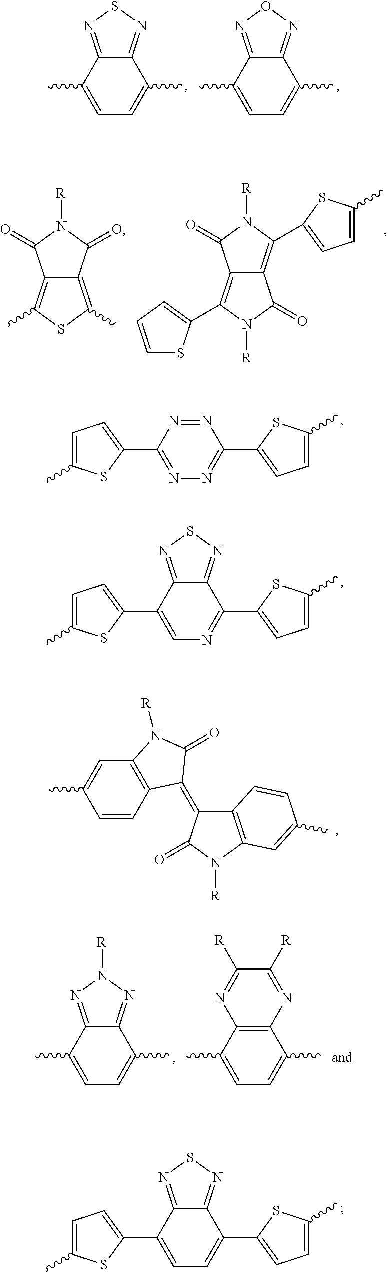
wherein, each R is independently selected from the group consisting of: H, C₁₋₃₀ alkyl, C₃₋₃₀ cycloalkyl, C₃₋₃₀ heterocycloalkyl, C₆₋₃₀ aryl, C₅₋₃₀ heteroaryl, —R₁COOR₁′, —R₂COR₂′, and —R₃—O—R₃′; in which each R₁, R₂ and R₃ is independently a bond or C₁₋₃₀ alkyl, and each R₁′, R₂′ and R₃′ is independently H or C₁₋₃₀ alkyl.

3. The polymer as claimed in claim 2, wherein A is isoindigo.

4. The polymer as claimed in claim 1, wherein when both m and m′ are 1, and p is 2, the polymer is represented by the following formula (2): 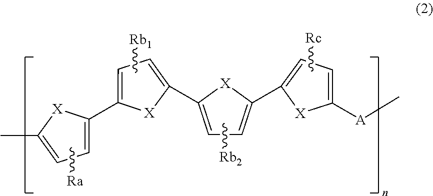
wherein both Rb₁ and Rb₂ are H, and Ra is identical to Rc.

5. The polymer as claimed in claim 4, wherein A is isoindigo.

6. The polymer as claimed in claim 4, wherein both Ra and Rc are C₁₋₃₀ alkyl.

7. The polymer as claimed in claim 1, wherein when both m and m′ are 2, and p is 1, the polymer is represented by the following formula (3): 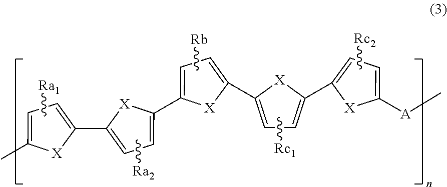
wherein Rb is H, and all Ra₁, Ra₂, Rc₁ and Rc₂ are identical.

8. The polymer as claimed in claim 7, wherein A is isoindigo.

9. The polymer as claimed in claim 7, wherein all Ra₁, Ra₂, Rc₁ and Rc₂ are C₁₋₃₀ alkyl.

10. The polymer as claimed in claim 1, wherein when both m and m′ are 2, and p is 2, the polymer is represented by the following formula (4): 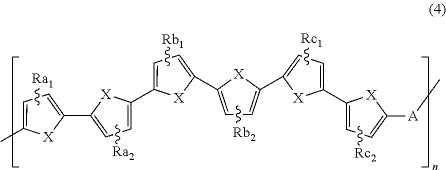
wherein both Rb₁ and Rb₂ are H, and all Ra₁, Ra₂, Rc₁ and Rc₂ are identical.

11. The polymer as claimed in claim 10, wherein A is isoindigo.

12. The polymer as claimed in claim 10, wherein all Ra₁, Ra₂, Rc₁ and Rc₂ are C₁₋₃₀ alkyl.

13. A polymer solar cell device, comprising:
a first electrode;
an active layer deposited on the first electrode, wherein a material thereof comprises: an n-type semiconductor material; and a p-type semiconductor material made of a polymer, which is represented by the following formula (1): 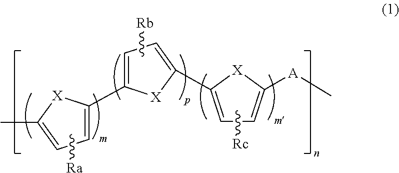
wherein,
X is O, N, S, Se, Te or Po;
each A is independently a substituted or unsubstituted functional group containing at least one aryl or heteroaryl;
each Ra, Rb and Rc is independently selected from the group consisting of: H, C₁₋₃₀ alkyl, C₃₋₃₀ cycloalkyl, C₃₋₃₀ heterocycloalkyl, C₆₋₃₀ aryl, C₅₋₃₀ heteroaryl, —R₁COOR₁′, —R₂COR₂′, and —R₃—O—R₃′; in which each R₁, R₂ and R₃ is independently a bond or C₁₋₃₀ alkyl, and each R₁′, R₂′ and R₃′ is independently H or C₁₋₃₀ alkyl;
m, m′ and p is independently an integer;
m+m′+p=4˜10;
m=m′; and
n=10˜150; and
a second electrode deposited on the active layer.

14. The polymer solar cell device as claimed in claim 13, wherein the n-type semiconductor material comprises at least one selected from the group consisting of: a nano carbon cluster, an n-type semiconductor polymer, and n-type semiconductor nanoparticles.

15. The polymer solar cell device as claimed in claim 14, wherein the nano carbon cluster is PC₆₁BM, PC₇₁BM, or a combination thereof.

16. The polymer solar cell device as claimed in claim 13, wherein the material of the active layer further comprises: an addictive comprising at least one of 1,8-diiodooctane (DIO) and 1-chloronaphthalene (CN).

17. The polymer solar cell device as claimed in claim 13, wherein the first electrode is a transparent electrode.

18. The polymer solar cell device as claimed in claim 13, wherein the second electrode is made of at least one selected from the group consisting of Al, Ca, Ag and Au.

19. The polymer solar cell device as claimed in claim 13, further comprising a hole transporting layer deposited between the first electrode and the active layer.
